(19) United States
(12) Patent Application Publication
(10) Pub. No.: US 2010/0219452 A1
(43) Pub. Date: Sep. 2, 2010

(54) GaN HIGH ELECTRON MOBILITY TRANSISTOR (HEMT) STRUCTURES

(76) Inventor: STEVEN K. BRIERLEY, Westford, MA (US)

Correspondence Address: RAYTHEON COMPANY;c/o DALY, CROWLEY, MOFFORD & DURKEE, LLP, 354A TURNPIKE STREET, SUITE 301A, CANTON, MA, 02021-2714, US

(21) Appl. No.: 12/394,182

(22) Filed: Feb. 27, 2009

(51) Int. Cl. H01L 29/778; H01L 21/335

(52) U.S. Cl. 257/194; 438/172; 257/E29.246; 257/E21.403

(57) ABSTRACT

A GaN HEMT structure having: a first III-N layer on GaN; a source electrode in contact with a first surface portion the first III-N layer disposed over a first region in the GaN layer; a drain electrode in contact with a second surface portion of the first III-N layer disposed over a second region in the GaN layer; a gate electrode disposed over a third surface portion of the first III-N layer, such third surface portion being disposed over a third region in the GaN layer. The GaN layer has: a fourth region therein disposed between the first region therein and the third region; and a fifth region therein disposed between the third region therein and the second region therein. A second III-N layer is disposed over the first III-N layer for generating a two-dimensional electron gas density in the GaN density in at least one of the fourth region and fifth region greater than the density in the third region of the GaN layer.

### TECHNICAL FIELD

This invention relates generally to GaN HEMT structures and more particularly to GaN HEMT structures having III-N compound layers on a GaN.

### BACKGROUND

As is known in the art, in order to obtain high efficiency and output power in GaN HEMTs, the on-resistance must be very low. This resistance is dominated by the access resistance between the source and gate and between the gate and drain. The traditional way around this problem is to dope part of the AlGaN Schottky layer and then recess the gate to remove the doping in the gate region. The drawback to this approach is that the additional charge that can be transferred to the induced 2-dimensional electron gas (2DEG) through AlGaN doping is limited to the high 10¹² cm⁻² range, which does not provide much differential charge density.

The inventor has recognized that in the standard GaN HEMT structures, increasing the 2DEG density so as to reduce the access resistance will also increase the sheet charge density in the gate region, thus increasing the field near the gate region, which reduces the breakdown voltage, and potentially degrades reliability. The induced 2DEG density in “simple” GaN HEMT structure (FIG. 1A) is a result of the electric fields created by the highly polar nature of the III-N compounds. Here, the HEMT structures include an epitaxial GaN buffer layer on which is grown an epitaxial AlGaN Schottky layer. Source (S), Drain (D) and Gate (G) contacts are provided as shown. Specifically, the 2DEG in the AlGaN is controlled by the composition and thickness of the AlGaN Schottky layer grown on the GaN buffer: A higher Al composition yields a larger 2DEG density, and a thicker AlGaN layer (up to a point) also yields a larger 2DEG (FIG. 2).

As is also known, devices with this epitaxial structure have resulted in good RF performance, but because of there are only two degrees of freedom in the design of the AlGaN Schottky layer, compromises must be made which limit the performance of these devices. Specifically, there is the same 2DEG density throughout the structure, whereas ideally, one would like to have a much higher charge density outside the gate region in order to provide a lower on-resistance.

Because of the highly polarized nature of the nitride compounds and the high charge densities at the interfaces between dissimilar III-N layers, the 2DEG density can be altered by adding other epitaxial layers, specifically, an additional cap layer above the AlGaN (e.g., a GaN cap in FIGS. 1B and 1C). If the cap layer has more Al than the AlGaN layer, the underlying sheet charge is increased (FIG. 3 shows the results for a pure AlN cap); if the cap layer has less Al, the sheet charge is decreased (FIG. 4 shows the results for a pure GaN cap).

Previously, various researchers have investigated the effect of continuous cap layers, especially GaN, spanning the entire from the source to the drain contacts.

The inventor has recognized that one can take advantage of the charge-altering effect of different cap layers by only employing them selectively within the source-drain region to achieve the modulation of charge along the desired channel. This provides a means of varying the 2DEG charge density along the HEMT channel without having to resort to impurity doping of the AlGaN Schottky layer.

Applicant has recognized that by combining a cap layer and selective etching a GaN HEMT structure can be created that distributes the density of the 2DEG along the channel in a more favorable manner for high performance. The objective is to keep the 2DEG sheet charge under the gate the same as in the simple structure, while increasing the sheet charge outside the gate area. This is accomplished with either of two different structures that are essentially mirror images of each other: 1) a “pedestal” GaN cap structure, or 2) a recessed AlN cap structure.

Thus, the invention uses the highly polarized nature of the III-N compounds to create a more complex layer structure that substantially alters the density of the 2DEG and then selectively etches that structure to remove the extra charge density where is not wanted. For the pedestal structure, a GaN cap layer is grown on top of an AlGaN Schottky layer which has a much higher than normal Al composition (which in the absence of the GaN cap would result in a significantly increased 2DEG sheet charge compared to that induced by a standard AlGaN Schottky layer). The GaN cap is then etched away outside the gate region. This leaves the higher sheet charge in the etched region and the lower sheet charge under the GaN cap.

For the recess structure, an AlN layer (or very high Al fraction AlGaN layer) is grown on top of the standard AlGaN Schottky layer, inducing a 2DEG charge density up to 1.5×10¹³ cm⁻² or higher. A GaN cap layer may or may not be grown on top of the AlN layer. In the gate and drift region the additional layer(s) is (are) etched away to leave a more “normal” 2DEG density under the gate, thus maintaining high breakdown voltage.

In accordance with the present invention, a GaN HEMT structure is provided having a GaN layer; a first III-N layer on a surface of the GaN layer, such first III-N layer generating a substantially uniform two-dimensional electron gas density in the GaN layer; a source electrode in contact with a first surface portion of the surface of the first III-N layer, such first surface portion being disposed over a first region in the GaN layer; a drain electrode in contact with a second surface portion of the surface of the first III-N layer, the first surface portion being laterally spaced from the second surface portion such second surface portion being disposed over a second region in the GaN layer; a gate electrode disposed between the source electrode and the drain electrode over the first III-N layer for controlling carriers between the source electrode and the drain electrode, such gate electrode being disposed over a third surface portion of the surface of the first III-N layer, such third surface portion being disposed over a third region in the GaN layer. The GaN layer has: a fourth region therein disposed between the first region therein and the third region; and a fifth region therein disposed between the second region therein and the third region therein. The structure includes a second III-N layer disposed over the first III-N layer for altering the substantially uniform two-dimensional electron gas density in the GaN into a two-dimensional electron gas density having a sheet charge in at least one of the fourth region and fifth region greater than the sheet charge of the two-dimensional electron gas density in the third region of the GaN layer.

In one embodiment, a GaN HEMT structure is provided having: a GaN layer; a first III-N layer on a surface of the GaN layer; a source electrode in contact with a first surface portion of the surface of the first III-N layer, such first surface portion being disposed over a first region in the GaN layer; a drain electrode in contact with a second surface portion of the surface of the first III-N layer, the first surface portion being laterally spaced from the second surface portion such second surface portion being disposed over a second region in the GaN layer; a gate electrode disposed between the source electrode and the drain electrode over the first III-N layer for controlling carriers between the source electrode and the drain electrode, such gate electrode being disposed over a third surface portion of the surface of the first III-N layer, such third surface portion being disposed over a third region in the GaN layer. The GaN layer has: a fourth region therein disposed between the first region therein and the third region; and a fifth region therein disposed between the second region therein and the third region therein. A second III-N layer is disposed over the first III-N layer and laterally spaced from the source contact and the drain contact, such second III-N layer being disposed over at least one of the fourth region and the fifth region.

In one embodiment, the first III-N layer includes Al.

In one embodiment, wherein the second III-N layer includes GaN.

In one embodiment, the first III-N layer is AlGaN or AlN.

In one embodiment, the gate electrode has one portion thereof in Schottky contact with a first portion of the surface of the III-N layer and a second portion thereof elevated over a second portion of the surface of the III-N layer.

In one embodiment, the first III-N layer has a first recess in the first region, a second recess in the second region, and a third recess in the third region with non-recessed portions between the first, second and third recesses, and the gate electrode is disposed within the third recess; and wherein the second III-N layer is disposed on at least one of the non-recessed portions of the first III-N layer.

In one embodiment, a method is provided for forming a GaN HEMT structure. The method includes: forming a layer comprising a III-N compound on a surface of the GaN for generating a two-dimensional electron gas density in the GaN layer; selectively removing portions of the generating layer; and forming: a source electrode in contact with a first surface portion of the surface of the first III-N layer, such first surface portion being disposed over a first region in the GaN layer; a drain electrode in contact with a second surface portion of the surface of the first III-N layer, the first surface portion being laterally spaced from the second surface portion, such second surface portion being disposed over a second region in the GaN layer; a second III-N layer over the first III-N layer disposed on a third region of the GaN layer, leaving a fourth region between the first region and third region and a fifth region between the second region and third region; and a gate electrode disposed between the source electrode and the drain electrode over the first III-N layer for controlling carriers between the source electrode and the drain electrode, such gate electrode being disposed over a third surface portion of the surface of the first III-N layer, such third surface portion being disposed over a third region in the GaN layer. The remaining portions of the generating layer produce a two-dimensional electron gas density having a sheet charge in at least one of the fourth region and fifth region greater than the sheet charge of the two-dimensional electron gas density in the third region of the GaN layer.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIGS. 1A-1C are GaN HEMT structures according to the PRIOR ART.

FIG. 2 is a graph showing 2DEG density as a function of AlGaN thickness for different Al compositions of an AlGaN layer used in the GaN HEMT of FIG. 1A.

FIG. 3 is a graph showing 2DEG density as a function of the thickness of a pure AlN cap layer on top of a Schottky layer of the specified composition of a HEMT of FIG. 1A.

FIG. 4 is a graph showing 2DEG density as a function of the thickness of a pure GaN cap layer on top of a Schottky layer of the specified composition.

FIG. 5A is a GaN structure according to one embodiment of the invention;

FIG. 5B is a plot of the 2DEG density as laterally across a GaN layer in the structure of FIG. 5A and

FIG. 6 is a GaN structure according to another embodiment of the invention.

Like reference symbols in the various drawings indicate like elements.

### DETAILED DESCRIPTION

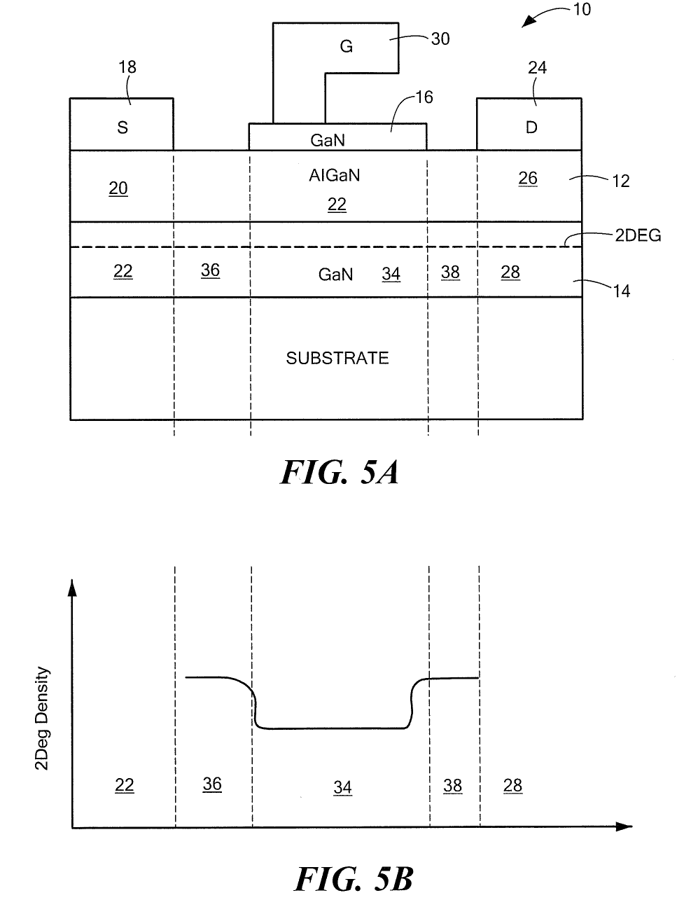

Referring now to FIG. 5A, a GaN HEMT structure 10 is shown. The structure 10 is formed by first forming an epitaxial layer 12 of a III-N compound, here AlGaN, on a GaN buffer layer 14. The III-N layer 12 generates a substantially uniform two-dimensional electron gas density in the GaN layer 14. Next, a layer 16 of III-N compound is formed on the epitaxial layer. Here, the III-N compound layer 16 is GaN. The III-N compound layer 16 is formed by first forming the layer of GaN over the entire surface of layer 12 and then selectively removing unwanted portions of the GaN using any lithographic-etching technique to leave the portion 16 shown in FIG. 5A.

A source electrode 18 is formed in ohmic contact with a first surface portion 20 of the surface of the III-N layer 12, such first surface portion 20 being disposed over a first region 22 in the GaN layer 14. A drain electrode 24 is formed in ohmic contact with a second surface portion 26 of the surface of the III-N layer 12, the first surface portion 20 being laterally spaced from the second surface portion 26, such second surface portion 26 being disposed over a second region 28 in the GaN layer 14. A gate electrode 30 is formed between the source electrode 18 and the drain electrode 24, such gate electrode 30 being formed in Schottky contact with III-N layer 16 for controlling carriers between the source electrode 18 and the drain electrode 24, such gate electrode 30 being disposed over a third surface portion 22 of the surface of the III-N layer 16, such third surface portion 22 being disposed over a third region 34 in the GaN layer 14. It is noted that the GaN layer 14 has: a fourth region 36 therein disposed between the first region 22 therein and the third region 34; and a fifth region 38 therein disposed between the third region 34 therein and the second region 28 therein. The III-N layer 16 alters the substantially uniform two-dimensional electron gas density in the GaN layer 14 into a two-dimensional electron gas density having a sheet charge in at least one of the fourth region 36 and fifth region 38 (here both regions 36, 38), greater than the sheet charge of the two-dimensional electron gas density in the third region 34 of the GaN layer 14, as shown in FIG. 5B.

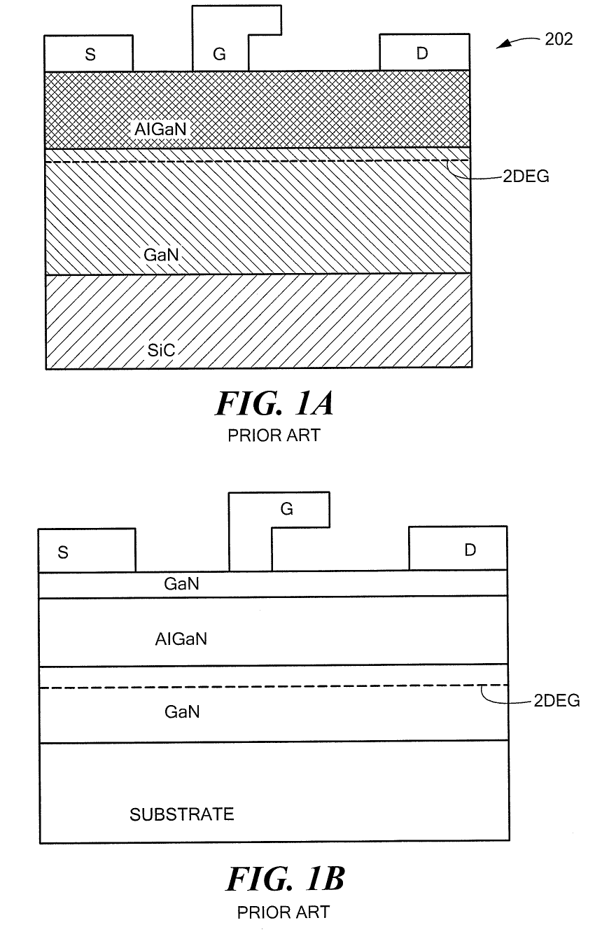

The resulting structure 10 is a pedestal GaN cap 16 structure. Recall that the GaN cap 16 suppresses the 2DEG sheet charge, the amount depending upon the thickness of the cap 16 (FIG. 4). In this structure 10, the AlGaN Schottky layer 12 has a higher Al composition than in the “standard” GaN HEMT structure (FIGS. 1A-1C). When the GaN cap 16 is grown on top of this higher Al GaN layer 12, the sheet charge where the GaN cap 16 remains is reduced. By adjusting the Al composition of the Schottky layer 12 and the GaN cap 16 thickness, one can match the 2DEG sheet charge of the standard HEMT configuration (FIG. 1A) with lower Al in the Schottky layer 12 and no GaN cap 16.

The charge engineering arises from the removal of the GaN cap 16 in regions other than under the gate (and, possibly, in a drift region adjacent to the gate on the drain side). Where these portions of the GaN cap 16 are removed, the 2DEG sheet charge rises to the value corresponding to the (high Al content) AlGaN Schottky layer 12. Thus, the desired result is achieved of a lower sheet charge in the high-field region under and near the gate (to maintain breakdown) and higher sheet charge in the access regions to reduce the on-resistance.

One variant on this structure 10 is to partially recess the source and drain contacts into the AlGaN Schottky layer to lower the contact resistance and further reduce the on-resistance.

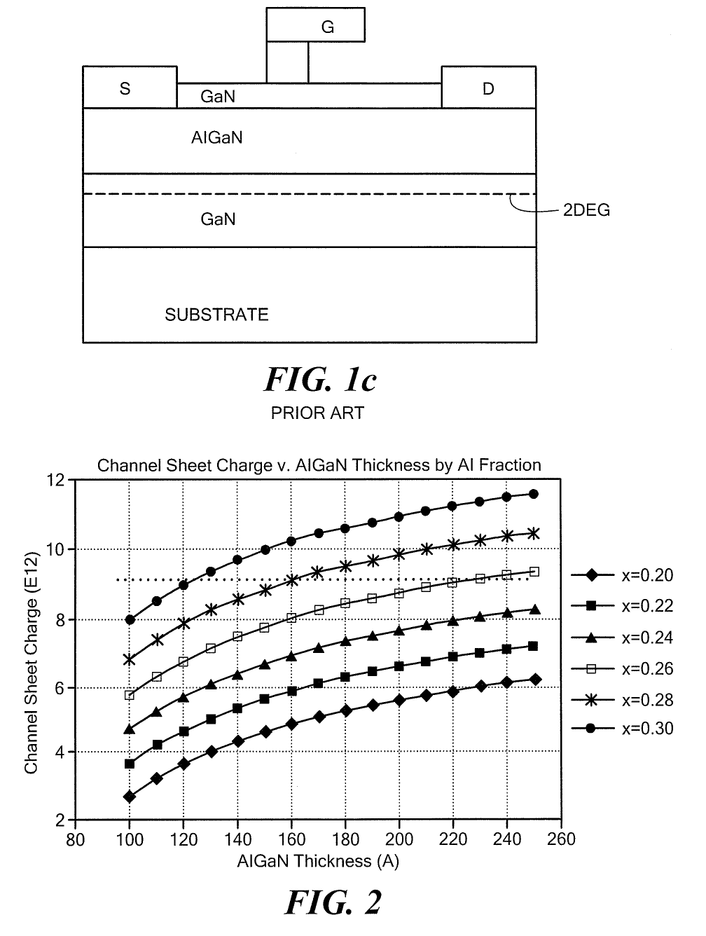

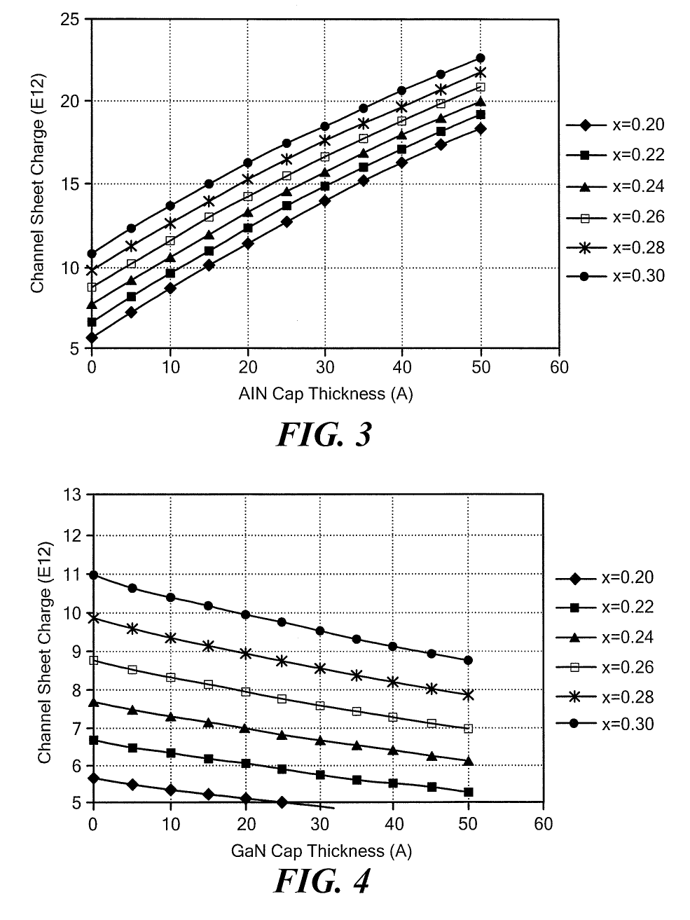

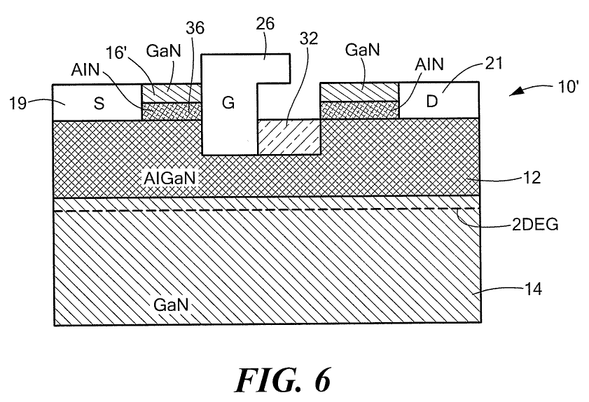

A recessed AlN structure 10′ is shown in FIG. 6. In this case, the Al fraction in the AlGaN Schottky layer 12 is the same as that in the standard HEMT of FIGS. 1A-1C. The addition of an AlN (or high Al composition AlGaN) cap layer 36 on top of the standard AlGaN Schottky layer 12 creates a very high 2DEG density (FIG. 3). Another GaN cap layer 16′ may or may not be added on top of the AlN layer 36 in order to modify the surface potential. Although the optional addition of this GaN cap 16′ reduces to some extent the charge-enhancing effect of the AlN layer 36, the net result is still a substantial increase in 2DEG sheet charge over that with the “standard” AlGaN structure (FIG. 1). Because of the complexity of the cap structure 16′, 36, the source and drain electrodes 19, 21 are recessed through the GaN/AlN cap layers 16′, 36 (and, perhaps, part way through the AlGaN Schottky layer 12) to achieve low contact resistance. The gate electrode 26 (and, possibly a drift region) is recessed completely through the GaN and AlN cap layers 16′, 36 and partially through the AlGaN Schottky layer 12. By removing the GaN/AlN cap layer 16′, 36, the extra induced two-dimensional electron gas charge that comes from the AlN (or high Al composition AlGaN) cap layer is eliminated; by continuing to etch through the AlGaN Schottky layer 12 the 2DEG charge is reduced even further through the effect of thinning the AlGaN (FIG. 2). The result is a device with a large difference in charge density between the non-recessed regions outside the gate area (high 2DEG density) and the recessed gate/drift region (normal/low charge density) thus optimizing the different regions for best HEMT performance. It is noted that a convention dielectric passivation material 32, such as for example, SiN, is included in the structure.

A number of embodiments of the invention have been described. Nevertheless, it will be understood that various modifications may be made without departing from the spirit and scope of the invention. Accordingly, other embodiments are within the scope of the following claims.

What is claimed is:

1. A GaN HEMT structure, comprising:
a GaN layer;
a first III-N layer on a surface of the GaN layer, such first III-N layer generating a substantially uniform two-dimensional electron gas density in the GaN layer;
a source electrode in contact with a first surface portion of the surface of the first III-N layer, such first surface portion being disposed over a first region in the GaN layer;
a drain electrode in contact with a second surface portion of the surface of the first III-N layer, the first surface portion being laterally spaced from the second surface portion such second surface portion being disposed over a second region in the GaN layer;
a gate electrode disposed between the source electrode and the drain electrode over the first III-N layer for controlling carriers between the source electrode and the drain electrode, such gate electrode being disposed over a third surface portion of the surface of the first III-N layer, such third surface portion being disposed over a third region in the GaN layer;
wherein the GaN layer has: a fourth region therein disposed between the first region therein and the third region; and a fifth region therein disposed between the third region therein and the second therein; and
a second III-N layer disposed over the first III-N layer for altering the substantially uniform two-dimensional electron gas density in the GaN into a two-dimensional electron gas density having a sheet charge in at least one of the fourth region and fifth region greater than the sheet charge of the two-dimensional electron gas density in the third region of the GaN layer.

2. A GaN HEMT structure, comprising:
a GaN layer;
a first III-N layer on a surface of the GaN layer;
a source electrode in contact with a first surface portion of the surface of the first III-N layer, such first surface portion being disposed over a first region in the GaN layer;
a drain electrode in contact with a second surface portion of the surface of the first III-N layer, the first surface portion being laterally spaced from the second surface portion such second surface portion being disposed over a second region in the GaN layer;
a gate electrode disposed between the source electrode and the drain electrode over the first III-N layer for controlling carriers between the source electrode and the drain electrode, such gate electrode being disposed over a third surface portion of the surface of the first III-N layer, such third surface portion being disposed over a third region in the GaN layer;
wherein the GaN layer has: a fourth region therein disposed between the first region therein and the third region; and a fifth region therein disposed between the second region therein and the third region therein; and
a second III-N layer disposed over the first III-N layer and laterally spaced from the source contact and the drain contact, such second III-N layer being disposed over at least one of the fourth region and the fifth region.

3. The structure recited in claim 2 wherein the two-dimensional electron gas density has a sheet charge under the gate electrode lower than the sheet charge of the two-dimensional electron gas density outside areas under the gate electrode.

4. The structure recited in claim 2 wherein the first III-N layer is a compound having Al and N.

5. The structure recited in claim 4 wherein the second III-N layer includes GaN or AlN or AlGaN.

6. The structure recited in claim 5 wherein the first III-N layer includes AlN.

7. The structure recited in claim 3 wherein the first III-N layer has a first recess in the first region, a second recess in the second region, and a third recess in the third region with non-recessed portions between the first, second and third recesses, and wherein the gate electrode is disposed within the third recess; and wherein the second III-N layer is disposed on at least one of the non-recessed portions of the first III-N layer.

8. The structure recited in claim 7 wherein the first III-N layer is a compound having Al and N.

9. The structure recited in claim 7 wherein the second III-N layer includes GaN.

10. The structure recited in claim 6 wherein the first III-N layer includes AlN.

11. A method for forming a GaN HEMT structure, comprising:
forming a layer comprising a III-N compound on a surface of GaN for generating a two-dimensional electron gas density in the GaN layer;
forming a second III-N compound layer for altering the two-dimensional charge density over the first III-N compound layer;
selectively removing portions of the second III-N compound layer
forming: a source electrode in contact with a first surface portion of the surface of the first III-N layer, such first surface portion being disposed over a first region in the GaN layer; a drain electrode in contact with a second surface portion of the surface of the first III-N layer, the first surface portion being laterally spaced from the second surface portion, such second surface portion being disposed over a second region in the GaN layer; and a gate electrode disposed between the source electrode and the drain electrode over the first III-N layer for controlling carriers between the source electrode and the drain electrode, such gate electrode being disposed over a third surface portion of the surface of the first III-N layer, such third surface portion being disposed over a third region in the GaN layer;
and wherein remaining portions of the charge altering layer produces a two-dimensional electron gas density having a sheet charge in at least one of the fourth region and fifth region greater than the sheet charge of the two-dimensional electron gas density in the third region of the GaN layer.

12. A GaN HEMT structure, comprising:
a GaN layer;
a first III-N layer on a surface of the GaN layer, such first III-N layer generating a substantially uniform two-dimensional electron gas density in the GaN layer;
a source electrode in contact with a first surface portion of the surface of the first III-N layer, such first surface portion being disposed over a first region in the GaN layer;
a drain electrode in contact with a second surface portion of the surface of the first III-N layer, the first surface portion being laterally spaced from the second surface portion such second surface portion being disposed over a second region in the GaN layer;
a second III-N layer for altering the substantially uniform two-dimensional electron gas density in the GaN disposed on a third surface portion of the surface of the first III-N layer, such third surface portion being disposed over a third region in the GaN layer between the source electrode and the drain electrode,
wherein the GaN layer has: a fourth region therein disposed between the first region therein and the third region; and a fifth region therein disposed between the third region therein and the second region therein,
wherein the two-dimensional electron gas has a sheet charge in at least one of the fourth region and fifth region greater than the sheet charge of the two-dimensional electron gas in the third region of the GaN layer, and
a gate electrode disposed between the source electrode and the drain electrode over the first III-N layer for controlling carriers between the source electrode and the drain electrode, such gate electrode being disposed on the surface of the second III-N layer, disposed over the third region in the GaN layer.

13. A GaN HEMT structure, comprising:
a GaN layer;
a first III-N layer on a surface of the GaN layer;
a source electrode in contact with a first surface portion of the surface of the first III-N layer, such first surface portion being disposed over a first region in the GaN layer;
a drain electrode in contact with a second surface portion of the surface of the first III-N layer, the first surface portion being laterally spaced from the second surface portion such second surface portion being disposed over a second region in the GaN layer;
a gate electrode disposed between the source electrode and the drain electrode over the first III-N layer for controlling carriers between the source electrode and the drain electrode, such gate electrode being disposed over a third surface portion of the surface of the first III-N layer, such third surface portion being disposed over a third region in the GaN layer;
wherein the GaN layer has: a fourth region therein disposed between the first region therein and the third region; and a fifth region their disposed between the third region therein and the third region therein; and
at least one additional III-N layer for altering the substantially uniform two-dimensional electron gas density in the GaN disposed over the first III-N layer and laterally spaced from the source contact and the drain contact, such second III-N layer being disposed over at least one of the fourth region and the fifth region,
wherein the two-dimensional electron gas has a sheet charge in at least one of the fourth region and fifth region greater than the sheet charge of the two-dimensional electron gas in the third region of the GaN layer.
